(19) United States
(12) Patent Application Publication
(10) Pub. No.: US 2008/0083984 A1
(43) Pub. Date: Apr. 10, 2008

(54) Wiring board

(75) Inventor: Takashi Kagawa, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC ELECTRONICS CORPORATION, Kawasaki (JP)

(21) Appl. No.: 11/905,721

(22) Filed: Oct. 3, 2007

(30) Foreign Application Priority Data
Oct. 6, 2006 (JP) 275633/2006

(51) Int. Cl. H01L 23/48; H05K 1/00

(52) U.S. Cl. 257/737; 174/250; 257/E23.01

(57) ABSTRACT

In a conventional wiring board, it is not possible to effectively attract electric charges provided by a charged body to a side surface of a wiring board and, therefore, it cannot be said that sufficient measures against static electricity have been taken for the wiring board. A wiring board including: an insulating layer (L2); a conductive layer (Lc2) overlaid on the insulating layer (L2); and an insulating layer (L1) overlaid oh the conductive layer (Lc2), wherein the conductive layer (Lc2) is connected to a ground potential node and is configured inclusive of a plane part (20) formed planar within the plane of the wiring board (SUB) and a plurality of protruding parts (21) extending from the plane part (20) toward the side faces of the wiring board (SUB), protruding faces (22) forming the front edges of the protruding parts (21) are exposed at the side faces of the wiring board (SUB), and thus a plurality of the protruding faces 22 are disposed at the side faces of the wiring board (SUB).

### BACKGROUND OF THE INVENTION

1. Field of the Invention

The present invention relates to a wiring board.

2. Description of the Related Art

A semiconductor element is mounted on a printed board or the like and is used in a variety of electronic apparatuses. The semiconductor element to be mounted includes an unpackaged semiconductor chip (a so-called bare chip) and a previously packaged semiconductor chip (for example, a ball grid array (BGA) package).

Incidentally, an electrostatic test is carried out in an electronic apparatus equipped with semiconductor elements as a test item at the time of product shipment (see Patent Document 1). Specifically, for example, a body charged with static electricity (charged body) is brought close to the electronic apparatus in which semiconductor elements have been previously mounted. At this point, a noncontact discharge may occur between the charged body and the conductor of the surface of the electronic apparatus. In order to prevent the electronic apparatus or semiconductor elements mounted therein from being functionally impaired, it is necessary to release electric charges provided to the electronic apparatus out of it without allowing them to pass through semiconductor chips.

Patent Document 1 shows an electronic apparatus wherein a wiring board is disposed in the housing of the electronic apparatus. Specifically, a conductor part connected to the ground line of the wiring board is provided in the outer circumferential part of the wiring board disposed within the housing. In addition, Patent Document 2 shows a printed wiring board wherein through-hole conductors connected to a grounding conductor are provided on peripheral edge parts of the printed wiring board.

[Patent Document 1]: Japanese Patent Laid-Open No. 2001-308586

[Patent Document 2]: Japanese Patent Laid-Open No. 5-63388

[Non-patent Document 1]: Transistor Gijutsu, August 2004 issue (p. 243)

A wiring board (semiconductor package board or printed board) on which such a semiconductor element as mentioned above is mounted is, for example, mounted on another wiring board, such as a printed board, through external terminals on the principal surface of the wiring board. The external terminals formed of solder ball pads and solder balls are often placed in a state of exposure as viewed from an end face of the wiring board. In this case, there is the possibility of an electrostatic discharge path, including these exposed external terminals, being formed. If these external terminals were signal terminals, a semiconductor chip (particularly the input/output circuits of the semiconductor chip) would be included in the discharge path and may suffer electrostatic breakdown.

In either case, Patent Document 1 or 2, it cannot be said that adequate consideration has been made with regard to a noncontact discharge path which may be formed between the charged body to be brought close to an end face of the wiring board and the wiring board. In other words, even if conductor parts connected to the ground line of the wiring board are simply provided in the peripheral parts of the wiring board or even if through-hole conductors connected to a grounding conductor are provided on peripheral edge parts of the printed wiring board, it is not possible to effectively attract electric charges provided by the charged body to end faces of the wiring board. As a result, there is the possibility of static electricity being provided to external terminals on the principal surface of the wiring board.

In the conventional wiring board, it has been not possible to effectively attract electric charges provided by a charged body to end faces of a wiring board and, therefore, it could not have been said that an adequate countermeasure against static electricity is taken.

### SUMMARY

A wiring board in accordance with the present invention includes:

a first insulating layer;

a first conductive layer formed over the first insulating layer; and

a second insulating layer formed over the first conductive layer,

wherein the board has a top surface and a side surface, and wherein the first conductive layer is parallel to said board and is coupled to receive a first power supply potential, the first conductive layer having a first portion and a second portion, the second portion including plurality of segments extending from the first portion to the side surface, so that edges of said segments are disposed at the side surface of the wiring board.

The first conductive layer is connected to the first power supply potential node or the second power supply potential node and is configured inclusive of the plane part formed planar within the plane of the wiring board and the plurality of protruding parts extending from the plane part toward the end faces of the wiring board. In addition, the protruding parts have the protruding faces exposed at the end faces of the wiring board. Consequently, a plurality of protruding faces are disposed at the end faces of the wiring board. Each of the plurality of protruding parts effectively functions as a conductor rod. Electric charges flowing through discharge paths are effectively attracted to each protruding part. Consequently, electric charges provided by the charged body are effectively attracted to the end faces of the wiring board.

In a wiring board in accordance with the present invention, since electric charges provided by a charged body can be effectively attracted to the end faces of a wiring board, it is possible to effectively protect a semiconductor element (particularly a semiconductor chip) to be mounted on the wiring board from static electricity.

### BRIEF DESCRIPTION OF THE DRAWINGS

FIG. 1 is a schematic perspective view of a semiconductor package including a wiring board in accordance with a first embodiment;

FIG. 2 is a schematic exploded perspective view of a semiconductor package;

FIG. 3 is a schematic top view of a semiconductor package;

FIG. 4 is a schematic bottom view of a semiconductor package;

FIG. 5 is a schematic left side elevational view of a semiconductor package;

FIG. 6 is a schematic right side elevational view of a semiconductor package;

FIG. 7 is a schematic cross-sectional view of a semiconductor package along the line A-A of FIG. 1;

FIG. 8 is a schematic explanatory view illustrating superposition of patterns;

FIG. 9 is another schematic referential view illustrating superposition of patterns;

FIG. 10 is a schematic top view of a semiconductor package including a wiring board in accordance with a second embodiment;

FIG. 11 is a schematic left side elevational view of the semiconductor package shown in FIG. 5;

FIG. 12 is a schematic bottom view of a semiconductor package corresponding to FIG. 4;

FIG. 13 is a schematic right side elevational view of the semiconductor package shown in FIG. 6;

FIG. 14 is a schematic cross-sectional view of a semiconductor package corresponding to FIG. 7;

FIG. 15 is a schematic top view of a semiconductor package including a wiring board in accordance with a third embodiment;

FIG. 16 is a schematic bottom view of a semiconductor package corresponding to FIG. 4;

FIG. 17 is a schematic cross-sectional view of a semiconductor package corresponding to FIG. 7;

FIG. 18 is a schematic side elevational view of a semiconductor package including a wiring board in accordance with a fourth embodiment;

FIG. 19 is another schematic side elevational view of a semiconductor package including a wiring board in accordance with a fourth embodiment; and

FIG. 20 is a schematic view of a pattern when a conductive layer Lc2 in accordance with a fifth embodiment is viewed from the top surface thereof.

### DETAILED DESCRIPTION OF THE PREFERRED EMBODIMENTS

Hereinafter, embodiments of the present invention will be described with reference to the accompanying drawings. It should be noted that the drawings are only schematic and, therefore, should not be interpreted as limiting the technical scope of the present invention, by using the representations of the drawings as a basis for such interpretation. It should also be noted that the same components are denoted by like numerals and symbols and will not be explained again. In addition, the drawings are exclusively for the purpose of explaining technical matters and do not reflect the precise sizes of components shown therein. Furthermore, in the description hereinafter made, it is assumed for the convenience of explanation that the paper surface of each drawing is viewed from the front thereof. Accordingly, the term “left, right, top and bottom” as used to specify a direction is based on the premise that the paper surface of each drawing is viewed from the front thereof.

### First Embodiment

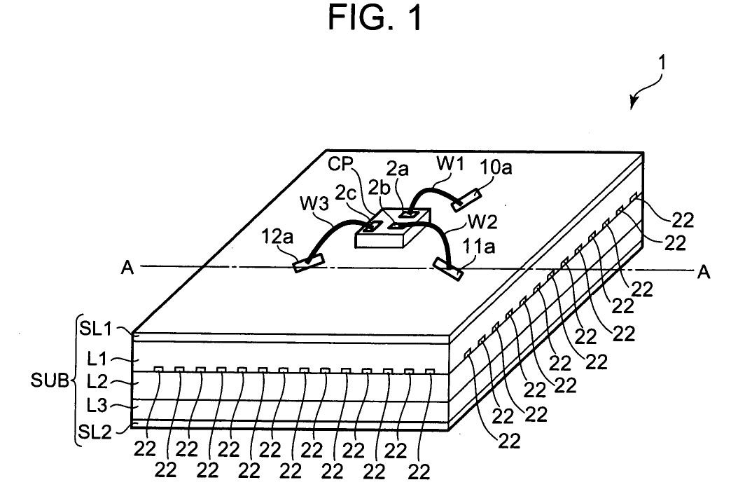

Now, a first embodiment of the present invention will be described with reference to FIGS. 1 to 7, wherein:

FIG. 1 is a schematic view showing a semiconductor package whereby an explanation is made of a wiring board in accordance with the first embodiment;

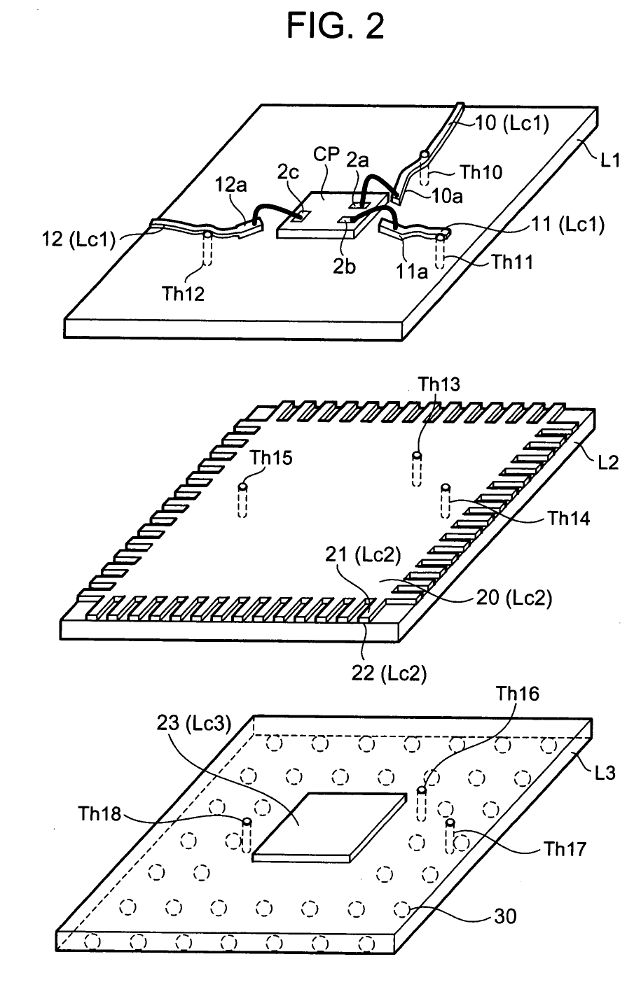

FIG. 2 is an exploded perspective view of the semiconductor package 1 shown in FIG. 1;

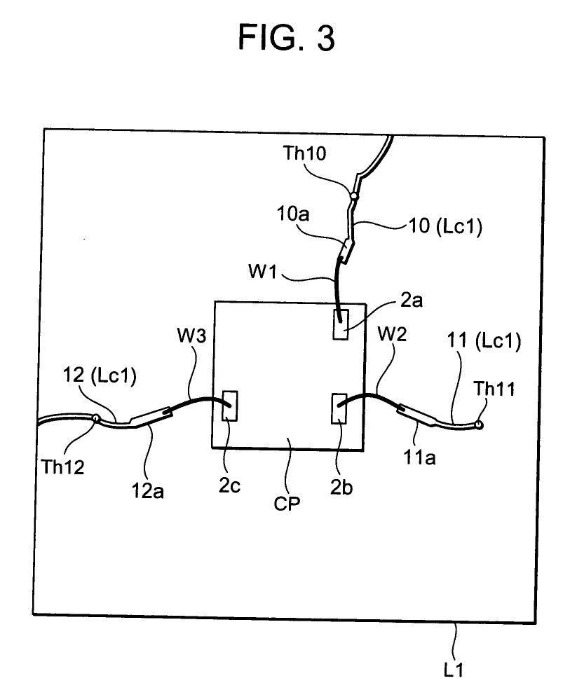

FIG. 3 is a top view of the semiconductor package 1;

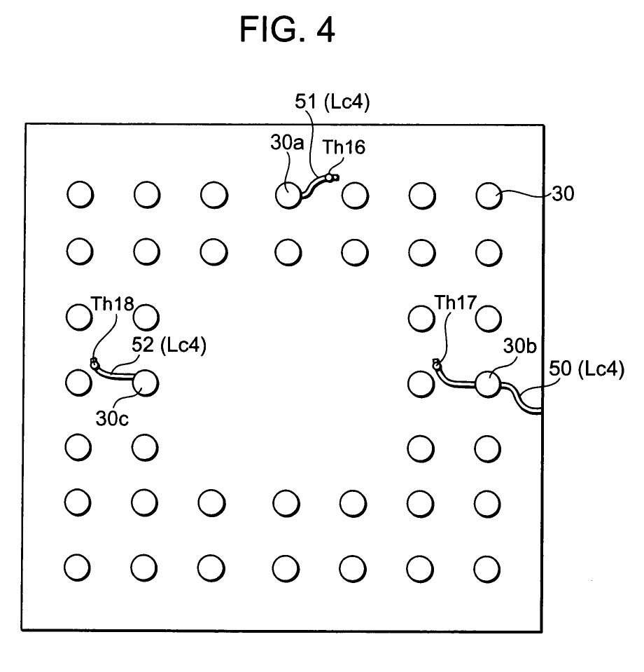

FIG. 4 is a bottom view of the semiconductor package 1;

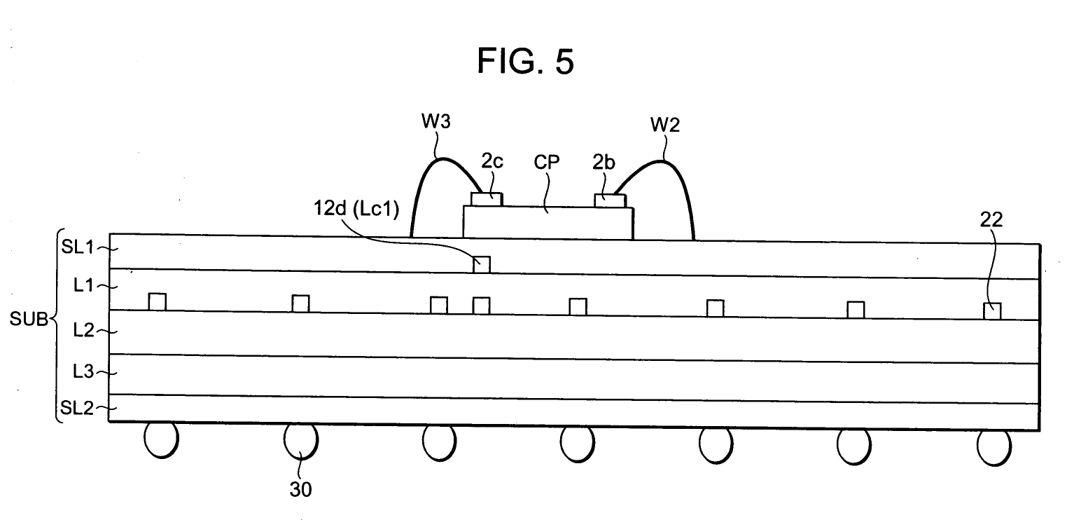

FIG. 5 is a left side elevational view of the semiconductor package 1;

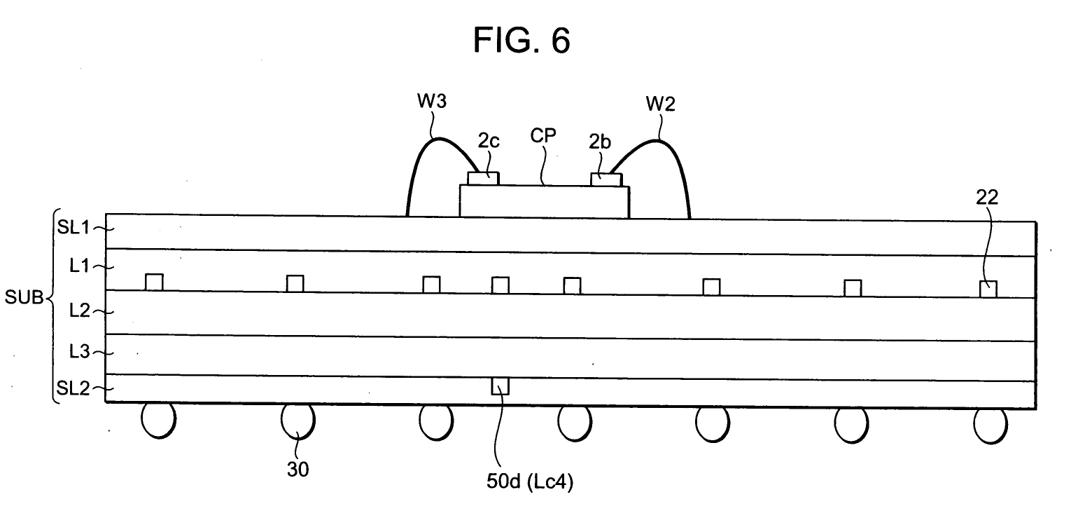

FIG. 6 is a right side elevational view of the semiconductor package 1; and

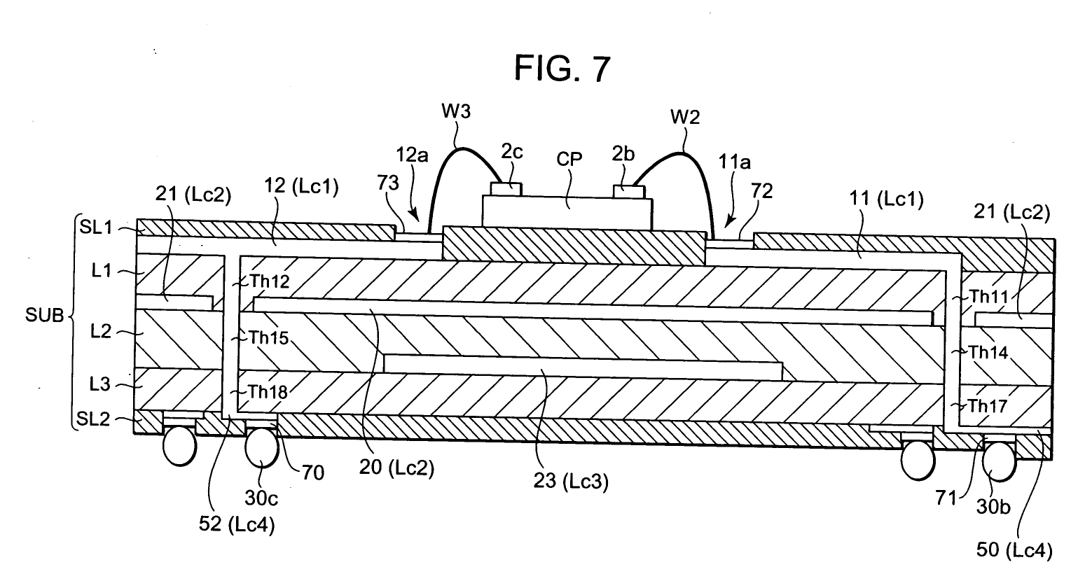

FIG. 7 is a cross-sectional view of the semiconductor package 1.

Note here that FIG. 7 is a simplified cross-sectional view along the A-A line of FIG. 1. In either one of FIG. 1 to 7, the semiconductor package 1 is a package configured by mounting a semiconductor chip CP on a wiring board SUB in accordance with the present invention.

First, as shown in FIG. 1, the semiconductor package 1 is provided with the wiring board SUB and the semiconductor chip CP. The semiconductor chip CP is mounted on the wiring board SUB. In addition, the wiring board SUB is mounted on another wiring board (mother board). Accordingly, the wiring board SUB equipped with the semiconductor chip CP is referred to here as a semiconductor package. The wiring board SUB is a daughter board in the sense that it is mounted on a mother board.

Note that the wiring board SUB in the present embodiment is used for, for example, a fine pitch ball grid array (FPBGA), a plastic ball grid array (PBGA), or the like. In this case, the semiconductor chip (bare chip) mounted on the wiring board SUB and the wiring board SUB are connected to each other using wires. In addition, connection terminals for connection with wires (so-called stitches) and solder balls are provided on the principal surface of the wiring board SUB. A film of nickel-gold (Ni—Au) is formed by electroplating on the stitches or solder balls made of copper. This film forming is performed in order to, for example, ensure bonding strength when wires are bonded to the stitches.

FIG. 1 shows the wiring board SUB wherein a solder resist layer SL2, an insulating layer L3, an insulating layer L2, an insulating layer L1, and a solder resist layer SL1 are stacked, from bottom to top, in this order. The insulating layer L2 is overlaid on the insulating layer L3 with a conductive layer Lc3 to be described later held therebetween. The insulating layer L1 is overlaid on the insulating layer L2 with a conductive layer Lc2 to be described later held therebetween. Then, the insulating layers L1, L2 and L3 are thermocompression-bonded to each other with the conductive layers Lc2 and Lc3 held respectively between the insulating layers L1 and L2 and between the insulating layers L2 and L3. In addition, a conductive layer Lc1 to be described later is formed on the top surface of the insulating layer L1 and a conductive layer Lc4 to be described later is formed on the bottom surface of the insulating layer L3. This means that the wiring board SUB is a multilayer wiring board in which insulating layers and conductive layers are alternately stacked, and is configured by stacking the solder resist layer SL2, the conductive layer Lc4 (fourth conductive layer), the insulating layer L3 (third insulating layer), the conductive layer Lc3 (second conductive layer)., the insulating layer L2 (first insulating layer), the conductive layer Lc2 (first conductive layer), the insulating layer L1 (second insulating layer), the conductive layer Lc1 (third conductive layer), and the solder resist layer SL1, in this order. The insulating layers L1 to L3 are formed of, for example, a resin material (glass epoxy resin or the like) which is softened by heating. The conductive layers Lc1 to Lc4 are formed of a metal material such as copper (cu). In addition, the conductive layer Lc4 (not shown in the figure) and solder ball pads (not shown in the figure) to be described later are formed on the bottom surface of the insulating layer L3. Note that when the wiring board SUB is mounted on another wiring board, solder balls 30 are disposed on the solder ball pads.

The wiring board SUB is a plate-like substrate and has a top surface (first principal surface) and a bottom surface (second principal surface) opposite to the top surface. In addition, the wiring board SUB ensures electrical connection between the semiconductor chip CP mounted on the top surface and the later-described solder balls 30 mounted on the bottom surface. Note that the top surface and the bottom surface of the wiring board SUB are equally formed of rectangular shape. The side surfaces of the wiring board SUB are formed as surfaces for connecting between the outer circumference of the bottom surface and the outer circumference of the top surface of the wiring board SUB. The wiring board SUB has four side surfaces in correspondence with the rectangular top and bottom surfaces. Note that the specific shape of the wiring board SUB may be polygonal (for example, L-shaped) and the top surface (or the bottom surface) may be shaped as having a curved surface such as a C-shaped surface.

The solder resist layer SL1 is formed on the top surface of the insulating layer L1. The solder resist layer SL1 protects wiring lines formed on the top surface of the insulating layer L1. The solder resist layer SL2 is formed on the bottom surface of the insulating layer L3. The solder resist layer SL2 protects wiring lines formed on the bottom surface of the insulating layer L3.

The semiconductor chip CP is a so-called bare chip and is disposed on the solder resist layer SL1. The semiconductor chip CP has terminals 2a, 2b and 2c on the top surface thereof. The terminal 2a of the semiconductor chip CP is connected through a wire W1 to a stitch (pedestal part) 10a exposed out of the solder resist layer SL1. Likewise, the terminal 2b of the semiconductor chip CP is connected through a wire W2 to a stitch (pedestal part) 11a exposed out of the solder resist layer SL1. Still likewise, the terminal 2c of the semiconductor chip CP is connected through a wire W3 to a stitch (pedestal part) 12a exposed out of the solder resist layer SL1. Note that as will be described later, the stitches 10a, 11a and 12a are regions where pads on the conductive layer Lc1 are exposed.

In the present embodiment, a plurality of protruding faces 22 are disposed on the side surfaces of the wiring board SUB. The protruding faces 22 form the front edges of protruding parts 21 to be described later. The protruding parts 21 effectively function as conductor rods. Consequently, electric charges provided by a charged body located near a side surface of the wiring board SUB (static electricity produced near a side surface of the wiring board SUB) are effectively attracted to the protruding faces 22 of the protruding parts 21. Accordingly, it is possible to prevent the electric charges from being discharged to external terminals (for example, solder balls 30 to be described later) or the like disposed on the principal surface of the wiring board SUB. Consequently, it is possible to effectively protect the semiconductor chip CP from suffering electrostatic breakdown. This means that if the external terminals (solder balls 30 to be described later) or the like are protected from static electricity, it is possible to effectively protect the semiconductor chip CP from electrostatic breakdown. Note that a plurality of protruding faces 22 are respectively disposed also on the side surfaces of the wiring board SUB not shown in FIG. 1.

Next, an explanation will be made of the internal structure of the semiconductor package 1 using an exploded perspective view thereof shown in FIG. 2. Note that in FIG. 2, the solder resist layers SL1 and SL2 are omitted for the convenience of explanation.

In FIG. 2, there are shown, from bottom to top, the insulating layer L3, the conductive layer Lc3, the insulating layer L2, conductive layer Lc2, the insulating layer L1 and conductive layer Lc1. The conductive layer Lc3 is formed on the insulating layer L3. The conductive layer Lc2 is formed on the insulating layer L2. The conductive layer Lc1 is formed on the insulating layer L1. Note that the conductive layer Lc4 (not shown in the figure) is formed below the insulating layer L3. In addition, the solder balls 30 (schematically illustrated by dotted lines) are disposed below the insulating layer L3.

First, an explanation will be made of the configuration of the conductive layers Lc1 to Lc3 shown in FIG. 2. As shown in FIG. 2, the conductive layer Lc1 is a so-called surface wiring layer and has wiring line 10, 11 and 12. That is, the conductive layer Lc1 is formed inclusive of a plurality of electrically isolated wiring lines. The respective wiring line 10, 11 and 12 ensure electrical connection between the terminals of the semiconductor chip CP and via holes (the insides of which are filled with a conductive member) provided in the insulating layer L1.

The wiring line 10 has the stitch 10a and extends to a via hole Th10, starting from the stitch 10a. As described above, one end of the wire W1 is connected to the terminal 2a of the semiconductor chip CP and the other end thereof is connected to the stitch 10a. Consequently, the terminal 2a of the semiconductor chip CP is connected to the wiring line 10 through the wire W1.

The wiring line 11 has the stitch 11a and extends to a via hole Th11, starting from the stitch 11a. As described above, one end of the wire W2 is connected to the terminal 2b of the semiconductor chip CP and the other end thereof is connected to the stitch 11a. Consequently, the terminal 2b of the semiconductor chip CP is connected to the wiring line 11 through the wire W2.

The wiring line 12 is the same in configuration as the wiring line 10. In other words, the stitch 12a corresponds to the stitch 10a and the wire W3 corresponds to the wire W1. Note that one end of the wire W3 is connected to the terminal 2c of the semiconductor chip CP.

The conductive layer Lc2 is formed on the top surface of the insulating layer L2. As shown in FIG. 2, the conductive layer Lc2 has a plane part 20 and a plurality of protruding parts 21. The plane part 20 is formed across the internal region of the top surface of the insulating layer L2. The protruding parts 21 are formed in the peripheral region (region surrounding the internal region) of the insulating layer L2. The plane part 20 is a so-called ground plane and is connected to a ground potential node (second power supply potential node). As described in the present embodiment, the plane part 20 is preferably formed in the central region, among internal regions of the top surface of the insulating layer L2. Note that as will be clarified in a description to be made later, the conductive layer Lc2 has a plurality of land parts (not shown in the figure) electrically isolated from the plane part 20. Also note that these land parts are formed in a plurality of hole parts provided in the plane part 20.

In the present embodiment, a plurality of protruding parts 21 are integrally formed around the plane part 20. The protruding parts 21 extend from the plane part 20 toward edges (sides whereby the top surface of the insulating layer L2 is defined) between the top and side surfaces of the insulating layer L2. (That is at least one of protruding parts 21 extends from the plane part 20 to the side surfaces of the wiring board SUB.) Each of the protruding parts 21 projecting from the plane part 20 extends toward a side surface closest to a solder ball 30, among the side surfaces of the wiring board SUB. At this point, a predetermined space exists between mutually adjacent protruding parts 21. In addition, the protruding parts 21 extend so that the front edges thereof reach edges between the top and side surfaces of the insulating layer L2. That is, the conductive layer L2 has a plurality of protruding parts 21 formed of comb-like shape within the plane of the wiring board SUB. The plurality of protruding parts 21 formed of comb-like shape are provided in correspondence with the side faces of the wiring board SUB. In addition, the protruding faces 22 of the plurality of protruding parts 21 formed of comb-like shape are exposed at the respective four side surfaces of the wiring board SUB. As a result, a plurality of protruding faces 22 are disposed in arrays at the respective side surfaces of the wiring board SUB along the width direction of the wiring board SUB (direction perpendicular to the direction in which the insulating layers constituting the wiring board SUB are stacked, which also applies hereinafter).

Note that the term “comb-like” as used herein represents a condition in which a plurality of protruding parts 21 are formed in arrays on the insulating layer L2 along the width direction of the wiring board SUB. Accordingly, the shape of the protruding parts 21 themselves is discretional. In other words, the top-view shape of the protruding parts 21 is not limited to a rectangle. Although the area of each protruding face 22 varies depending on the top-view shape of the protruding parts 21, the functionality of the protruding parts 21 as conductor rods is not impaired as long as the protruding faces 22 are exposed at the side surfaces of the wiring board SUB. Note that the protruding parts 21 extend toward the protruding faces 22 with substantially the same width, as shown in FIG. 2. (That is at least one of protruding parts 21 has its width substantially the same as it extends from the plane part 20 to the side surfaces of the wiring board SUB.) Such a configuration of protruding parts as described above can be achieved by making the protruding parts the same in shape as wiring lines in the wiring board SUB.

In the present embodiment, the width of the protruding face 22 of each of the protruding parts 21 along the width direction of the wiring board SUB is sufficiently smaller than the width of the plane part 20 along the width direction of the wiring board SUB. In general, electric charges converge more densely on a portion shaper in shape. For this reason, electric charges converge on corner parts of the protruding parts 21. Consequently, even if structured so as to extend toward the protruding faces 22 with substantially the same width, as shown in FIG. 2, the protruding parts 21 are still subject to a discharge onto the corner parts of the front edges (protruding faces 22) thereof. Accordingly, it can be said that the protruding parts 21 are adapted to effectively function as conductor rods.

In addition, in the present embodiment, each of the protruding parts 21 projecting from the plane part 20 extends toward a side surface closest to a solder ball 30, among the side surfaces of the wiring board SUB. In addition, the protruding parts 21 preferably extend to a position immediately above a position where a solder ball is visible when viewed from a side of the semiconductor package 1. As a result, the protruding faces 22 are disposed in the vicinity of solder balls 30 to be protected. Consequently, it is possible to effectively protect the solder balls 30 to be protected from static electricity.

As described above, when the conductive layer Lc2 is formed, the protruding faces 22 forming the front edges of the protruding parts 21 are exposed at the side surfaces of the wiring board SUB shown in FIG. 1 and a plurality of protruding faces 22 are disposed at the side surfaces of the wiring board SUB. Note here that the protruding faces 22 forming the front edges of the protruding parts 21 substantially correspond to the side faces of the wiring board SUB.

The conductive layer Lc3 is formed on the top surface of the insulating layer L3. As shown in FIG. 2, the conductive layer Lc3 has a plane part 23. The plane part 23 is formed of planar shape in an internal region within the plane of the insulating layer L3. The plane part 23 is a so-called power supply plane and is connected to a power supply potential node (first power supply potential node). Note that, as will be clarified in a description made later, the conductive layer Lc3 has a plurality of land parts (not shown in the figure) electrically isolated from the power supply plane. Also note that the land parts may be formed separately from the plane part 23 or may be formed in hole parts (not shown in the figure) provided in the plane part 23.

Now, an explanation will be made of electrical paths from the semiconductor chip CP on the top surface of the insulating layer L1 to the bottom surface of the insulating layer L3, using FIG. 2.

The insulating layer L1 has via holes Th10, Th11 and Th12 which function as electrical paths between the top and bottom surfaces of the insulating layer L1. The insulating layer L2 has via holes Th13, Th14 and Th15 which function as electrical paths between the top and bottom surfaces of the insulating layer L2. The insulating layer L3 has via holes Th16, Th17 and Th18 which function as electrical paths between the top and bottom surfaces of the insulating layer L3. Note that the inside of each via hole is filled with a conductive member (descriptions will be made hereinafter on the premise that the inside of each via hole is filled with a conductive member).

As described above, the terminal 2a of the semiconductor chip CP is connected to the wiring line 10. The terminal 2b of the semiconductor chip CP is connected to the wiring line 11. Likewise, the terminal 2c of the semiconductor chip CP is connected to the wiring line 12. In addition, the wiring line 10 extends over the via hole Th10 and is electrically connected thereto. The wiring line 11 extends over the via hole Th11 and is electrically connected thereto. The wiring line 12 extends over the via hole Th12 and is electrically connected thereto.

Accordingly, an electrical connection path is formed from the terminal 2a of the semiconductor chip CP to the bottom surface of the insulating layer L1 through the wire W1, wiring line 10, and via hole Th10. Likewise, an electrical connection path is formed from the terminal 2b of the semiconductor chip CP to the bottom surface of the insulating layer L1 through the wire W2, wiring line 11, and via hole Th11. An electrical connection path is also formed from the terminal 2c of the semiconductor chip CP to the bottom surface of the insulating layer L1 through the wire W3, wiring line 12, and via hole Th12.

As a result of the insulating layers L1 and L2 being thermocompression-bonded to each other, the via hole Th10 of the insulating layer L1 is electrically connected to the via hole Th13 of the insulating layer L2. Consequently, an electrical connection path is formed by the via hole Th13 from the terminal 2a of the semiconductor chip CP to the bottom surface of the insulating layer L2. Note that in correspondence with the via holes Th10 and Th13, the plane part 20 has land parts (not shown in the figure) for connecting the via hole Th10 with the via hole Th13. With these land parts, the via holes Th10 and Th13 are excellently connected to each other.

Likewise, as a result of the insulating layers L1 and L2 being thermocompression-bonded to each other, the via hole Th11 of the insulating layer L1 is electrically connected to the via hole Th14 of the insulating layer L2. Consequently, an electrical connection path is formed by the via hole Th14 from the terminal 2b of the semiconductor chip CP to the bottom surface of the insulating layer L2. Note that in correspondence with the via holes Th11 and Th14, the plane part 20 has land parts (not shown in the figure) for connecting the via hole Th11 with the via hole Th14. With these land parts, the via holes Th11 and Th14 are excellently connected to each other.

Likewise, as a result of the insulating layers L1 and L2 being thermocompression-bonded to each other, the via hole Th12 of the insulating layer L1 is electrically connected to the via hole Th15 of the insulating layer L2. Consequently, an electrical connection path is formed by the via hole Th15 from the terminal 2c of the semiconductor chip CP to the bottom surface of the insulating layer L2. Note that in correspondence with the via holes Th12 and Th15, the conductive layer Lc2 has land parts (not shown in the figure) for connecting the via hole Th12 with the via hole Th15. With these land parts, the via holes Th12 and Th15 are excellently connected to each other.

As a result of the insulating layers L2 and L3 being thermocompression-bonded to each other, the via hole Th13 of the insulating layer L2 is electrically connected to the via hole Th16 of the insulating layer L3. Consequently, an electrical connection path is secured by the via hole Th16 from the terminal 2a of the semiconductor chip CP to the bottom surface of the insulating layer L3. Note that in correspondence with the via holes Th13 and Th16, the conductive layer Lc3 has land parts (not shown in the figure) for connecting the via hole Th13 with the via hole Th16. With these land parts, the via holes Th13 and Th16 are excellently connected to each other.

As a result of the insulating layers L2 and L3 being thermocompression-bonded to each other, the via hole Th14 of the insulating layer L2 is electrically connected to the via hole Th17 of the insulating layer L3. Consequently, an electrical connection path is secured by the via hole Th17 from the terminal 2b of the semiconductor chip CP to the bottom surface of the insulating layer L3. Note that in correspondence with the via holes Th14 and Th17, the conductive layer Lc3 has land parts (not shown in the figure) for connecting the via hole Th14 with the via hole Th17. With these land parts, the via holes Th14 and Th17 are excellently connected to each other.

Likewise, as a result of the insulating layers L2 and L3 being thermocompression-bonded to each other, the via hole Th15 of the insulating layer L2 is electrically connected to the via hole Th18 of the insulating layer L3. Consequently, an electrical connection path is secured by the via hole Th18 from the terminal 2c of the semiconductor chip CP to the bottom surface of the insulating layer L3. Note that in correspondence with the via holes Th15 and Th18, the conductive layer Lc3 has land parts (not shown in the figure) for connecting the via hole Th15 with the via hole Th18. With these land parts, the via holes Th15 and Th18 are excellently connected to each other.

In this way, an electrical connection path is secured from the semiconductor chip CP mounted on the top surface of the wiring board SUB to the bottom surface of the wiring board SUB.

The conductive layer Lc4 (not shown in the figure) is formed on the bottom surface of the wiring board SUB (insulating layer L3). In addition, as schematically shown in FIG. 2, a plurality of solder balls 30 are disposed on the bottom surface of the insulating layer L3 in a two-dimensional manner.

Like the conductive layer Lc3, the conductive layer Lc4 is a so-called surface wiring layer and is formed inclusive of a plurality of electrically isolated wiring lines. The via hole Th16 and a solder ball 30a to be described later are connected to each other by a wiring line constituting the conductive layer Lc4. Consequently, there is secured an electrical path from the terminal 2a of the semiconductor chip CP to the solder ball 30a. In addition, the via hole Th17 and a solder ball 30b to be described later are connected to each other by a wiring line constituting the conductive layer Lc4. Consequently, there is secured an electrical path from the terminal 2b of the semiconductor chip CP to the solder ball 30b. In addition, the via hole Th18 and a solder ball 30c are connected to each other by a wiring line constituting the conductive layer Lc4. Consequently, there is secured an electrical path from the terminal 2c of the semiconductor chip CP to the solder ball 30c.

In this way, the terminals of the semiconductor chip CP disposed on the top surface of the wiring board SUB are electrically connected to the solder balls 30 on the bottom surface of the wiring board SUB through the via holes respectively formed in the insulating layers L1 to L3.

Note that, in the present embodiment, although an explanation has been made only of the electrical path from the terminal 2a of the semiconductor chip CP to the solder ball 30a, of the electrical path from the terminal 2b of the semiconductor chip CP to the solder ball 30b, and of the electrical path from the terminal 2c of the semiconductor chip CP to the solder ball 30c, the number of electrical paths may increase or decrease depending on the circuit scale of the semiconductor chip. Note that since data signals are provided to the above-described three electrical paths, these electrical paths are referred to as signal lines for convenience's sake. In addition, as is evident from the foregoing description, these signal lines are isolated from the plane part 20 of the conductive layer Lc2 and from the plane part 23 of the conductive layer Lc3.

Note that although not illustrated in the drawing, the plane part 20 of the conductive layer Lc2 is connected to the ground terminal of the semiconductor chip CP. The plane part 20 is also connected to the solder balls 30 to be connected to the ground. In other words, according as described above, the plane part 20 formed on the conductive layer Lc2 is connected to the ground terminal (not shown in the figure) of the semiconductor chip CP through via holes (not shown in the figure) formed in the insulating layer L1, wiring lines (not shown in the figure) formed on the top surface of the insulating layer L1, and wires (not shown in the figure). In addition, the plane part 20 formed on the conductive layer Lc2 is connected to the solder balls 30 to be connected to the ground, through via holes (not shown in the figure) formed in the insulating layers L2 and L3 and wiring lines (not shown in the figure) formed on the bottom surface of the insulating layer L3.

Note that although not illustrated in the drawing either, the plane part 23 of the conductive layer Lc3 is connected to the power supply terminal of the semiconductor chip CP. The plane part 23 is also connected to the solder balls 30 to be connected to a power supply. In other words, according as described above, the plane part 23 formed on the conductive layer Lc3 is connected to the power supply terminal (not shown in the figure) of the semiconductor chip CP through via holes (not shown in the figure) formed in the insulating layers L1 and L2, wiring lines (not shown in the figure) formed on the top surface of the insulating layer L1, and wires (not shown in the figure). In addition, the plane part 23 formed on the conductive layer Lc3 is connected to the solder balls 30 to be connected to the power supply, through via holes (not shown in the figure) formed in the insulating layer L3 and wiring lines (not shown in the figure) formed on the bottom surface of the insulating layer L3.

With the plane parts 20 and 23, it is possible to simplify the wiring structure of the wiring board SUB and stabilize power supply potential. It is also possible to implement noise countermeasures for signals.

Hereinafter, an explanation will be made specifically of the configurations of the top, bottom and side surfaces of the semiconductor package 1, using FIGS. 3 to 6. Note that the solder resist layers SL1 and SL2 shown in FIG. 1 are also omitted here for the convenience of explanation.

As shown in FIG. 3, in the present embodiment, the semiconductor chip CP is mounted in a semiconductor chip mounting region in the center of the top surface of the wiring board SUB. In addition, the stitches 10a to 12a are disposed in the peripheral region of the semiconductor chip mounting region.

The wiring line 10 connects the semiconductor chip CP with the via hole Th10, as described above, and extends beyond the via hole Th10 to a side surface of the wiring board SUB, as shown in FIG. 3. In addition, the wiring line 10 reaches an edge (side whereby the top surface of the insulating layer L1 is defined) between the top and side surfaces of the insulating layer L1.

The wiring line 11 extends to the via hole Th11, starting from the stitch 11a. In other words, the wiring line 11 does not reach an edge (side whereby the top surface of the insulating layer L1 is defined) between the top and side surfaces of the insulating layer L1.

The wiring line 12 connects the semiconductor chip CP with the via hole Th12, as described above, and extends beyond the via hole Th12 to a side surface of the wiring board SUB, like the wiring line 10. In addition, the wiring line 12 reaches an edge (side whereby the top surface of the insulating layer L1 is defined) between the top and side surfaces of the insulating layer L1.

As shown in FIG. 4, in the present embodiment, a plurality of solder balls 30 are placed on the bottom surface of the semiconductor package 1.

The plurality of solder balls 30 are disposed on solder ball pads formed on the bottom surface of the conductive layer Lc4 of the wiring board SUB. In the present embodiment, the solder ball pads form external terminals. Wiring lines 50, 51 and 52 are also formed on the bottom surface of the conductive layer Lc4 of the wiring board SUB.

The wiring line 50 connects the via hole Th17 with the solder ball 30b and extends to a part where the solder ball 30b is to be disposed, starting from the via hole Th17. In addition, the wiring line 50 extends up to an edge (side whereby the top surface of the insulating layer L3 is defined) between the bottom and side surfaces of the insulating layer L3.

The wiring line 51 connects the via hole Th16 with the solder ball 30a. Likewise, the wiring line 52 connects the via hole Th1 with the solder ball 30c. Note that the wiring lines 51 and 52 do not extend up to edges (sides whereby the bottom surface of the insulating layer L3 is defined) between the bottom and side surfaces of the insulating layer L3.

As has been described earlier, a film of nickel-gold (Ni—Au) or the like is formed by electroplating on the stitches 10a, 11a and 12a and on the solder ball pads. When forming the film, the stitches 10a, 11a and 12a and the solder ball pads are used as electrodes. The reason for the wiring lines 10 and 12 of the conductive layer Lc1 and the wiring line 50 of the conductive layer Lc4 extending to side surfaces of the wiring board SUB is because the wiring lines 10, 12 and 50 are used as plated wires(or plated line). That is, the wiring lines 10, 12 and 50 extend up to side surfaces of the wiring board SUB, in order to be connected to an external power supply. In a wiring board to which an electroplating process is applied, plated wires may extend up to side surfaces of the wiring board and the end faces of wiring lines may be exposed at the side surfaces, as in the present embodiment.

FIG. 5 is a left side elevational view of the semiconductor package 1 when FIG. 1 is viewed from the front. As shown in FIG. 5, it is understood that a plurality of solder balls 30 are exposed when a view is taken of the left side surface of the semiconductor package 1. There are also exposed a plurality of protruding faces 22 of the protruding parts 21 constituting the conductive layer Lc2.

The solder balls 30 disposed on the bottom surface of the wiring board SUB are in a state of exposure. Consequently, it is easy for electric charges to be provided from a charged body near a side surface of the wiring board SUB to the solder balls 30. With this point in view, in the present embodiment, a plurality of protruding faces 22 are disposed in the vicinity of the solder balls 30 to be protected from static electricity. Electric charges provided by the charged body near a side surface of the wiring board SUB are attracted to the protruding faces 22 of the protruding parts functioning as conductor rods. As a result, the electric charges (static electricity) are inhibited from being provided to the solder balls 30 to be protected.

In addition, as shown in FIG. 5, the present embodiment is configured so that a front face 12d forming the front edge of the wiring line 12 constituting the conductive layer Lc1 is also exposed as a plated wire.

Consequently, in this case, electric charges can also be easily provided from the charged body near a side surface of the wiring board SUB to the front face 12d of the wiring line 12. In the present embodiment, a plurality of protruding faces 22 are disposed at the side surfaces of the wiring board SUB in order to protect solder balls 30. Consequently, a plurality of protruding faces 22 are also disposed in the vicinity of the front face 12d as a matter of course. Electric charges provided by the charged body near a side surface of the wiring board SUB are attracted to the protruding faces 22 of the protruding parts 21 functioning as conductor rods. As a result, electric charges (static electricity) are also inhibited from being provided to the front face 12d. Note that the semiconductor package 1 is configured so that the front face 12d of the wiring line 12 is disposed immediately above the protruding face 22. Also note that, as a rule, the terminals 2b and 2c and the wires W2 and W3 on the top surface of the semiconductor chip CP are configured so as not to suffer electrostatic breakdown, by covering with a resin the top surface of the wiring board SUB, along with the semiconductor chip CP, the terminals 2b and 2c, and the wires W2 and W3.

FIG. 6 is a right side elevational view of the semiconductor package 1. Note that FIG. 6 is a right side elevational view of the semiconductor package 1 when FIG. 1 is viewed from the front side thereof. As shown in FIG. 6, it is understood that a plurality of solder balls 30 are exposed when a view is taken of the right side surface of the semiconductor package 1. There are also exposed a plurality of protruding faces 22 of the protruding parts 21 constituting the conductive layer Lc2.

As described above, the solder balls 30 disposed on the bottom surface of the wiring board SUB are in a state of exposure. Consequently, electric charges can easily be provided from a charged body near a side surface of the wiring board SUB to the solder balls 30. With this point in view, in the present embodiment, a plurality of protruding faces 22 are disposed in the vicinity of the solder balls 30. Electric charges provided by the charged body near a side surface of the wiring board SUB are attracted to the protruding faces 22 of the protruding parts 21 functioning as conductor rods. Accordingly, the electric charges from the charged body are inhibited from being provided to the solder balls 30 to be protected. Note that the semiconductor package 1 is configured so that the solder balls 30 are disposed immediately below the protruding faces 22.

In addition, as shown in FIG. 6, the wiring board SUB is configured so that a front face 50d forming the front edge of the wiring line 50 constituting the conductive layer Lc4 is also exposed as a plating wire.

Consequently, in this case, electric charges can also be easily provided from the charged body near a side surface of the wiring board SUB to the front face 50d. In the present embodiment, a plurality of protruding faces 22 are disposed at the side surfaces of the wiring board SUB in order to protect the solder balls 30. Accordingly, a plurality of protruding faces 22 are also disposed in the vicinity of the front face 50d. Electric charges provided by the charged body near a side surface of the wiring board SUB are attracted to the protruding faces 22 of the protruding parts 21 functioning as conductor rods. As a result, electric charges (static electricity) are also inhibited from being provided to the front face 50d. In addition, the semiconductor package 1 is configured so that the front face 50d is disposed immediately below the protruding face 22.

As shown in FIG. 7, the terminal 2b of the semiconductor chip CP is connected to a solder ball 30b through the wire W2, the stitch 11a, the wiring line 11, the via hole Th11, the via hole Th14, the via hole Th17, the wiring line 50, and a nickel-gold (Ni—Au) film 71 formed on the same conductive layer (Lc4) as the wiring line 50. A solder ball pad, on which the solder ball 30b is mounted, is formed of the nickel-gold film 71 and the conductive layer (Lc4), the same as the wiring line 50 formed underneath the film 71. Note that a signal line between the terminal 2b and the solder ball 30b is electrically isolated from the above-described plane parts 20 and 23. In addition, the stitch 11a is formed into a two-layer structure composed of the wiring line 11 and a nickel-gold film 72 formed thereon.

The terminal 2c formed on the semiconductor chip CP is connected to the solder ball 30c through the wire W3, the stitch 12a, the wiring line 12, the via hole Th12, the via hole Th15, the via hole Th18, the wiring line 52, and a nickel-gold (Ni—Au) film 70 formed on the same conductive layer (Lc4) as the wiring line 52. A solder ball pad, on which the solder ball 30c is mounted, is formed of the nickel-gold film 70 and the conductive layer (Lc4), the same as the wiring line 52 formed underneath the film 70. Note that a signal line between the terminal 2c and the solder ball 30c is electrically isolated from the above-described plane parts 20 and 23. In addition, the stitch 12a is formed into a two-layer structure composed of the wiring line 12 and a nickel-gold film 73 formed thereon.

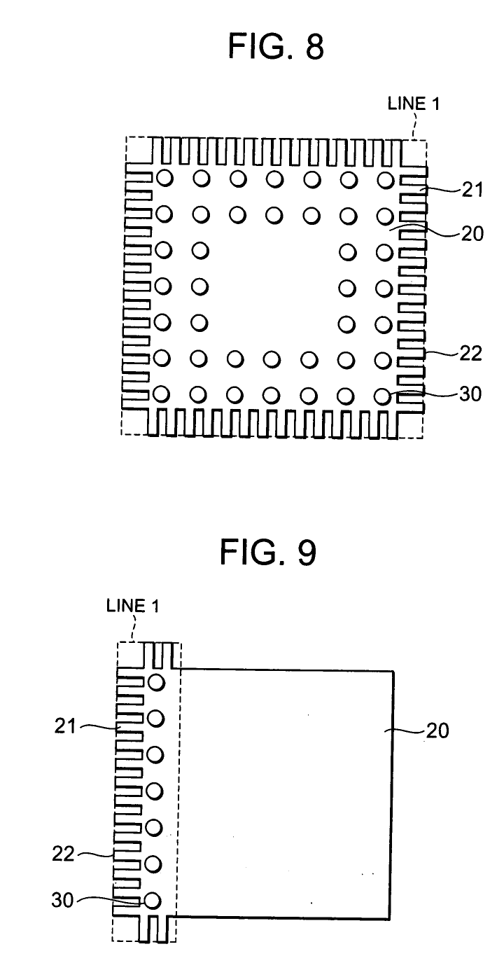

Now, there is shown a configuration in FIG. 8 wherein the pattern of the conductive layer Lc2 is superposed on the configurational pattern of the solder balls 30. As shown in FIG. 8, all of the solder balls 30 are disposed within an area enclosed by a dashed line (imaginary line) Line 1 defined by the protruding faces 22. Consequently, even if the semiconductor package 1 is mounted on another wiring board with the solder balls 30 exposed, electric charges provided by a charged body near a side surface of the wiring board SUB are effectively attracted to the protruding parts 21. As a result, the electric charges are inhibited from being provided to the solder balls 30. Consequently, for example, the semiconductor chip CP is protected from being functionally damaged.

A supplementary explanation will be made in this regard with reference to another reference drawing shown in FIG. 9. As shown in FIG. 9, the protruding parts 21 are disposed in correspondence with the positions in which the solder balls 30 are disposed. Here, the solder balls 30 are also disposed within an area enclosed by the dashed line Line 1 formed by connecting the protruding faces 22 of the protruding parts 21. Consequently, also in this case, the solder balls 30 are effectively protected from static electricity. In other words, it is only necessary that the protruding parts 21 be disposed in correspondence with the solder balls 30 to be protected. It is thus not essential that the protruding faces 22 be exposed at all of the four side surfaces of the wiring board SUB.

Also from this figure, one can understand the significance that each protruding part 21 projecting from the plane part 20 extends toward a side surface, among the side surfaces of the wiring board SUB, closest to the given solder ball 30. That is, each protruding part 21 extends toward a side surface closest to the solder ball 30 to be protected. Thus, each protruding face 22 is disposed at a side surface of the wiring board SUB closest to each given solder ball 30. Thus, the protruding faces 22 are disposed in the vicinity of the solder balls 30 to be protected. As a result, it is possible to effectively protect the solder balls 30 to be protected from static electricity.

As is evident from the foregoing description, in the present embodiment, the protruding faces 22 of the protruding parts 21 constituting the conductive layer Lc2 are exposed at the side surfaces of the wiring board SUB. Thus, a plurality of protruding faces 22 are disposed in arrays at the side surfaces of the wiring board SUB. Consequently, it is possible to protect the solder balls 30 mounted on the bottom surface of the wiring board SUB from static electricity present near the side surfaces of the wiring board SUB. This configuration is effective when the solder balls (projecting electrodes) 30 are mounted in a state of exposure on the bottom surface of the wiring board SUB, as in the present embodiment. In addition, by protecting the solder balls 30, it is possible to also protect from static electricity the terminals 2a, 2b and 2c on the semiconductor chip CP, the wiring lines 10 and 12 the front faces of which are exposed at side surfaces of the wiring board SUB, the wiring line 50 the front face of which is also exposed at a side surface of the wiring board SUB, and the films 70, 71, 72 and 73 constituting the stitches and solder ball pads. That is, it is possible to protect the stitches 10a and 12a and the solder ball pads (not shown in the figure) from static electricity.

In addition, in the present embodiment, since the protruding faces 22 are exposed at all of the side surfaces of the wiring board SUB, it is possible to protect the solder balls 30 from static electricity produced at any location in the vicinity of the side surfaces of the wiring board SUB. This is because static electricity produced in the vicinity of the side surfaces of the wiring board SUB is effectively attracted to the protruding parts 21 (protruding faces 22) functioning as conductor rods provided in all of the side surfaces of the wiring board SUB. Note that electric charges provided to the protruding parts 21 flow through the protruding parts 21 (conductive layer Lc2) into the ground.

Furthermore, in the present embodiment, a plurality of protruding parts 21 are formed in a peripheral part within the plane of the wiring board SUB. Accordingly, it is possible to utilize an existing dicing technique and manufacture the chipped wiring board SUB from a wafer-level wiring board, without decreasing the yield.

If the plane part 20 is formed as far as a peripheral part within the plane of the wiring board SUB, there is the possibility that the plane part 20 overextends along the side surfaces of the wiring board SUB when the wafer-level wiring board is diced. That is, burrs may be produced at side surfaces of the wiring board SUB. In the present embodiment, only a plurality of protruding parts 21 are formed in the peripheral part within the plane of the wiring board SUB. Consequently, burrs are inhibited from being produced at side surfaces of the wiring board SUB. This means that the yield of the wiring board SUB does not degrade.

In the present embodiment, the insulating layers L1, L2 and L3 are formed of a resin material and are thermocompression-bonded to each other. In addition, in the present embodiment, only a plurality of protruding parts 21 are formed in a peripheral part within the plane of the wiring board SUB. If the plane part 20 is formed as far as the peripheral part within the plane of the wiring board SUB, the adhesiveness of the insulating layers L1 and L2 is impaired. For example, the insulating layer L1 may peel off from the insulating layer L2 after the wiring board SUB is formed. However, in the present embodiment, since only a plurality of protruding parts 21 are formed in the peripheral part within the plane of the wiring board SUB, as described above, the adhesiveness of the insulating layers L1 and L2 is not impaired. Accordingly, there is no possibility of the insulating layer L1 peeling off from the insulating layer L2.

In addition, as a result of the protruding faces 22 of the protruding parts 21 being exposed at the side surfaces of the wiring board SUB, such a secondary effect as mentioned in the following description is gained. That is, a worker who handles the semiconductor package 1 touches the protruding faces 22 exposed at the side surfaces of the wiring board SUB constituting the semiconductor package 1. Consequently, electric charges carried by the worker himself or herself are discharged to the ground. That is to say, the protruding faces 22 serve as means alternative to a method of releasing electric charges (static electricity) using a grounding wristband.

Note that in the present embodiment, although the term “wiring board” is used as inclusive of the solder resist layers SL1 and SL2 and the conductive layers Lc1 and Lc4 for the convenience of explanation, the wiring board may be defined as exclusive of these components.

### Second Embodiment

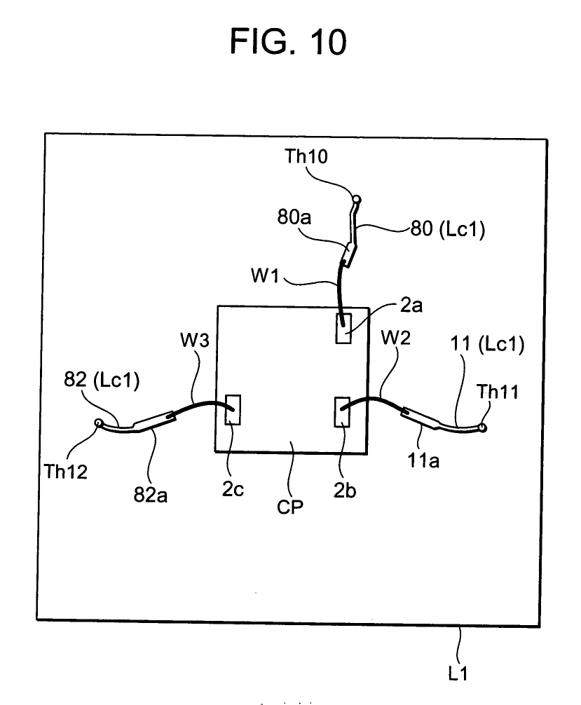

Hereinafter, an explanation will be made of a wiring board in accordance with a second embodiment using FIGS. 10 to 14. The second embodiment differs from the first embodiment in the pattern of the conductive layer Lc1 and in the pattern of the conductive layer Lc4. Accordingly, the explanation will be made with a focus on these differences. Note that in the present embodiment, a wiring board SUB is a wiring board requiring or not requiring electroplating, wherein plating wires, which are electrode wiring lines for electroplating, are removed from the wiring board. The wiring lines 10 and 12 shown in FIG. 3 and the wiring line 50 shown in FIG. 4 in the first embodiment correspond to a mode of carrying out the invention wherein these wiring lines are not exposed at side surfaces of the wiring board SUB. Note that Non-patent Document 1 describes the concept of removing unnecessary parts from the conductive layers Lc1 and Lc4 formed by means of electroplating after the formation of wiring lines.

FIG. 10 shows a top view corresponding to FIG. 3 in the first embodiment. A conductive layer Lc1 is formed on the top surface of an insulating layer L1. In the present embodiment, the conductive layer Lc1 is comprised of a wiring line 80 in place of the wiring line 10 shown in FIG. 3 and a wiring line 82 in place of the wiring line 12 shown in FIG. 3.

As shown in FIG. 10, the wiring line 80 has a stitch 80a. The wiring line 80 extends up to a position above a via hole Th10, starting from the stitch 80a, and is electrically connected to the via hole Th10. Note here that the wiring line 80 does not extend beyond the via hole Th10.

The wiring line 82 is the same in configuration as the wiring line 80. A stitch 82a corresponds to the stitch 80a and a via hole Th12 corresponds to the via hole Th10.

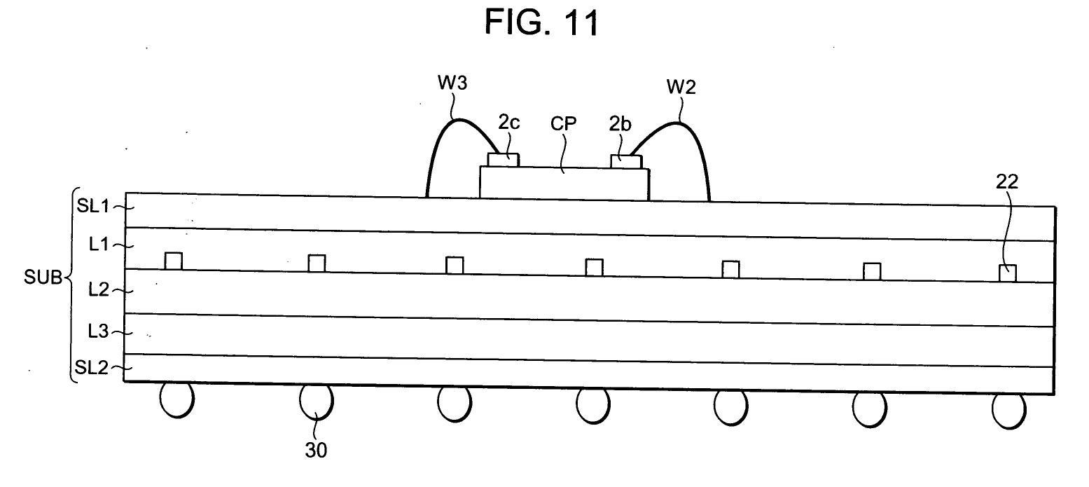

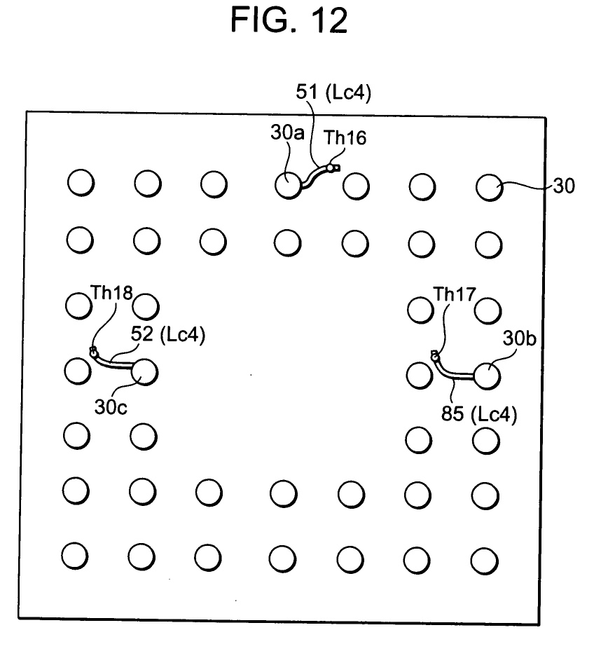

FIG. 11 shows a left side elevational view corresponding to FIG. 4 in the first embodiment. As described above, in the present embodiment, the wiring line 82 constituting the conductive layer Lc1 does not extend up to an edge (side whereby the top surface of the insulating layer L1 is defined) between the top and bottom surfaces of the insulating layer L1. The conductive layer Lc1, therefore, is not exposed at the left side surface of the semiconductor package, as shown in FIG. 11. Consequently, electric charges provided by a charged body near a side surface of the wiring board SUB are not provided to the conductive layer Lc1. Accordingly, it is possible to make measures against static electricity present near side surfaces of the wiring board SUB even more sufficient, compared with the first embodiment.

FIG. 12 shows a bottom view corresponding to FIG. 5 in the first embodiment. As shown in FIG. 12, a conductive layer Lc4 is formed on the bottom surface of the insulating layer L3. In the present embodiment, the conductive layer Lc4 has a wiring line 85 in place of the wiring line 50 in the first embodiment.

As shown in FIG. 12, the wiring line 85 connects a via hole Th17 with a solder ball 30b. The wiring line 85 extends up to a position where the solder ball 30b is to be disposed, starting from the via hole Th17. In the present embodiment, the wiring line 85 does not extend beyond the solder ball 30b.

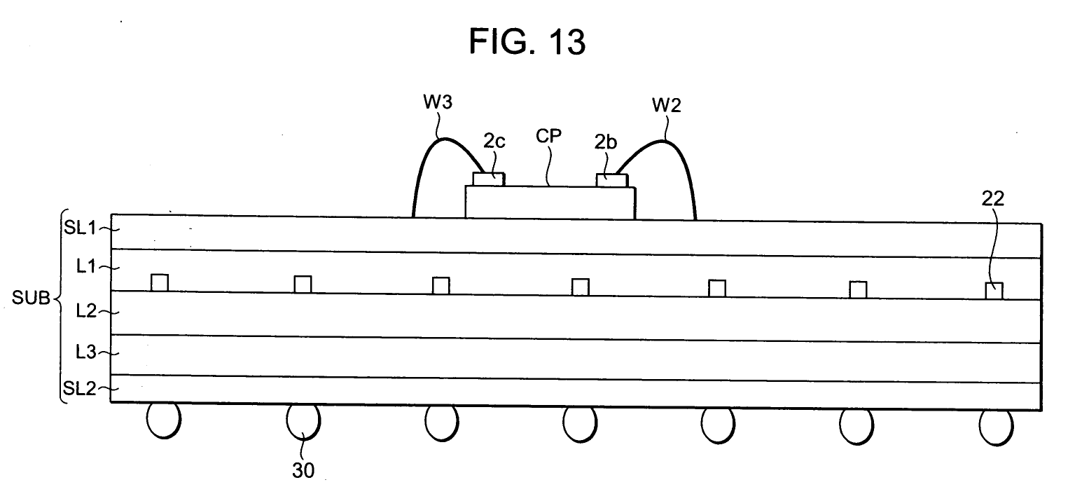

FIG. 13 shows a right side elevational view corresponding to FIG. 6 in the first embodiment. As shown in FIG. 13, in the present embodiment, the wiring line 85 constituting the conductive layer Lc4 does not extend up to an edge (side whereby the bottom surface of the insulating layer L4 is defined) between the bottom and side surfaces of the insulating layer L4. The conductive layer Lc4, therefore, is not exposed at a side surface of the wiring board SUB, as shown in FIG. 13. Consequently, electric charges provided by a charged body near a side surface of the wiring board SUB are not provided to the conductive layer Lc4. Accordingly, it is possible to make measures against static electricity present near side surfaces of the wiring board SUB even more sufficient, compared with the first embodiment.

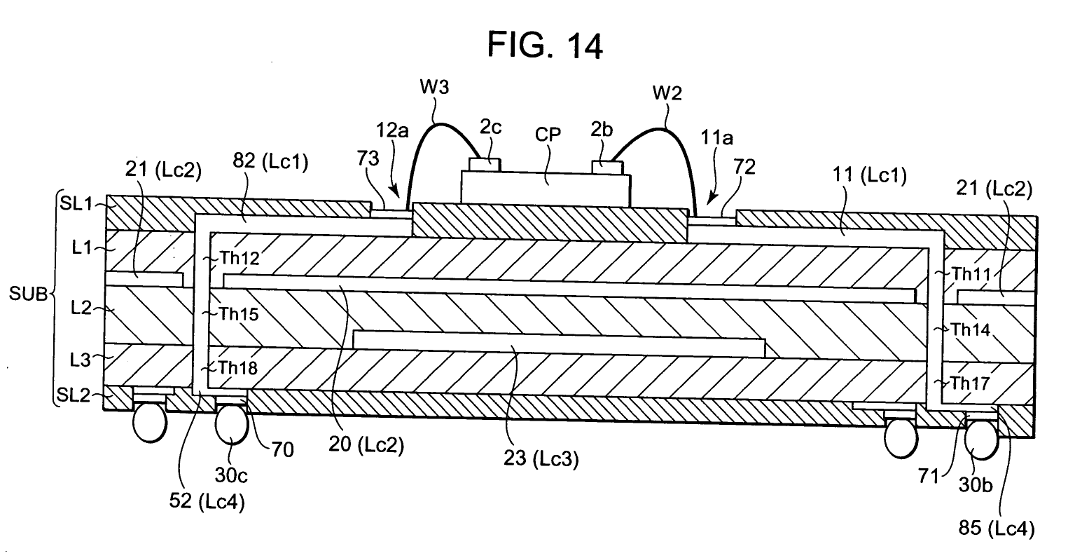

FIG. 14 shows a cross-sectional view corresponding to FIG. 7 in the first embodiment. As shown in FIG. 14, in the present embodiment, the wiring line 82 extends up to the via hole Th12 formed on the insulating layer L1 but does not extend beyond the via hole Th12. In addition, the wiring line 85 extends further from the via hole Th17 formed in the insulating layer L3 up to a position where the solder ball 30b is to be disposed, but does not extend beyond the position where the solder ball 30b is to be disposed.

In the present embodiment, the wiring lines 80, 82 and 85 formed in the conductive layers Lc1 and Lc4 are not exposed at side surfaces of the wiring board SUB. Consequently, electric charges provided by a charged body near a side surface of the wiring board SUB are not provided to the conductive layers Lc1 and Lc4. Accordingly, it is possible to make measures against static electricity present near side surfaces of the wiring board SUB even more sufficient, compared with the first embodiment.

Note that the second embodiment differs from the first embodiment only in that the wiring lines 10, 12 and 50 formed in the conductive layers Lc1 and Lc4 are not exposed at side surfaces of the wiring board SUB. It is thus evident that the configuration shown in the first embodiment may also be adopted for the rest of the configuration of the second embodiment.

### Third Embodiment

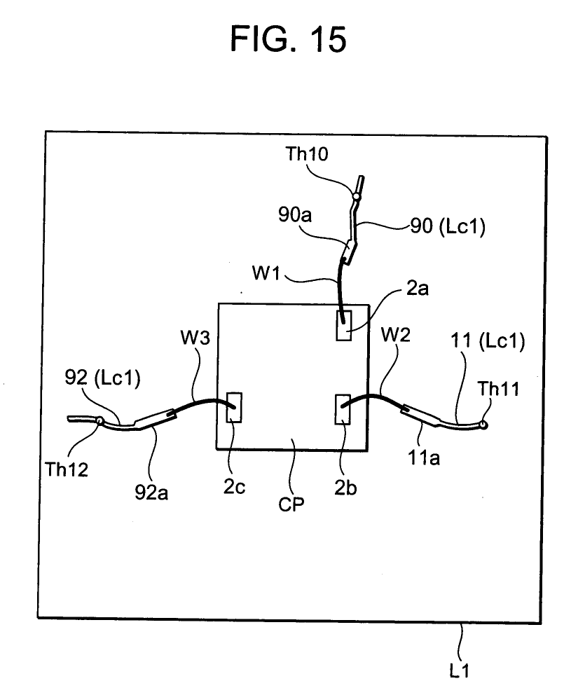

Hereinafter, an explanation will be made of a wiring board in accordance with a third embodiment using FIGS. 15 to 17. The third embodiment differs from the first embodiment in the pattern of the conductive layer Lc1 and in the pattern of the conductive layer Lc4. Accordingly, the explanation will be made with a focus on these differences. A wiring board SUB in accordance with the present embodiment is such that the parts of plating wires, which are electrode wiring lines for electroplating, to be exposed at side surfaces of the wiring board have been removed from the wiring board of the first embodiment.

FIG. 15 shows a top view corresponding to FIG. 3 in the first embodiment. As shown in FIG. 15, a conductive layer Lc1 is formed on the top surface of an insulating layer L1. In the present embodiment, the conductive layer Lc1 is formed inclusive of a wiring line 90 in place of the wiring line 10 shown in FIG. 3 and a wiring line 92 in place of the wiring line 12 shown in FIG. 3.

The wiring line 90 has a stitch 90a. The wiring line 90 extends up to a position above a via hole Th10, starting from the stitch 90a, and is electrically connected to the via hole Th10. The wiring line 90 has a wiring line formed as a plating wire but the part thereof to be exposed at a side surface of the wiring board has been removed. That is, the wiring line 90 does not extend up to an edge (side whereby the top surface of the insulating layer L1 is defined) between the top and side surfaces of the insulating layer L1.

The wiring line 92 is the same in configuration as the wiring line 90. A stitch 92a corresponds to the stitch 90a and a via hole Th12 corresponds to the via hole Th10. However, the wiring line 92 is electrically connected to the via hole Th12.

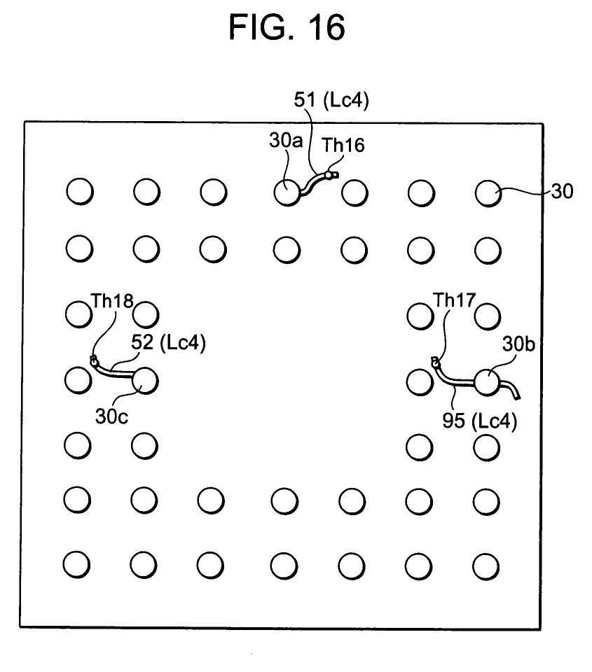

FIG. 16 shows a bottom view corresponding to FIG. 5 in the first embodiment. As shown in FIG. 16, the conductive layer Lc4 is formed on the bottom surface of the insulating layer L3. In the present embodiment, the conductive layer Lc4 is formed inclusive of a wiring line 95 in place of the wiring line 50 shown in FIG. 5.

The wiring line 95 connects the via hole Th17 with a solder ball 30b. The wiring line 95 extends up to a position where the solder ball 30b is to be disposed, starting from the via hole Th17. The wiring line 95 also has a wiring line formed as a plating wire but the part thereof to be exposed at a side surface of the wiring board SUB has been removed. That is, the wiring line 95 does not extend up to an edge (side whereby the bottom surface of the insulating layer L3 is defined) between the bottom and side surfaces of the insulating layer L3.

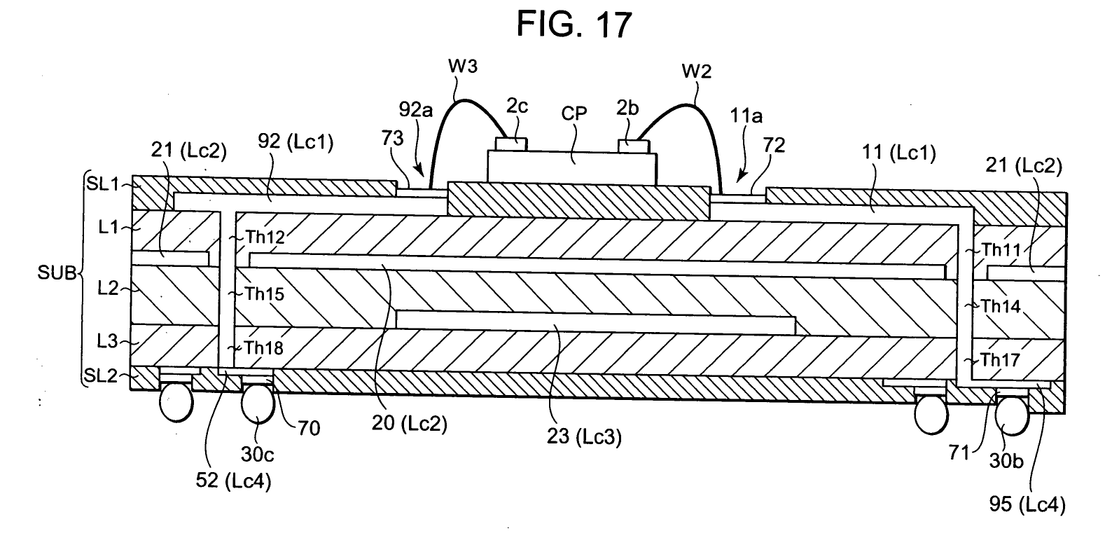

FIG. 17 shows a drawing corresponding to FIG. 7 in the first embodiment. As shown in FIG. 17, in the present, embodiment, the wiring line 92 extends to a position above the via hole Th12 formed in the insulating layer L1 and further extends beyond the via hole Th12. However, the wiring line 92 does not extend up to an edge between the top and side surfaces of the insulating layer L1. In addition, the wiring line 95 extends from the via hole Th17 formed in the insulating layer L3 to a position where the solder ball 30b is to be disposed, and further extends beyond the position where the solder ball 30b is to be disposed. However, the wiring line 95 does not extend up to an edge (side whereby the bottom surface of the insulating layer L3 is defined) between the bottom and side surfaces of the insulating layer L3.

In the present embodiment, as described above, the wiring lines 90, 92 and 95 formed in the conductive layers Lc1 and Lc4 are such that the parts of plating wires, which are electrode wiring lines for electroplating, to be exposed at side surfaces of the wiring board SUB have been removed from the wiring board SUB of the first embodiment. Consequently, the conductive layers Lc1 and Lc4 are not exposed at side surfaces of the wiring board SUB. Therefore, electric charges are not provided from a charged body near the wiring board SUB to the conductive layers Lc1 and Lc4. As a result, it is possible to make measures against static electricity present near side surfaces of the wiring board SUB even more sufficient, compared with the first embodiment. In this way, even if the wiring board SUB requires plating wires, it is still possible to configure the wiring board SUB in accordance with the present embodiment by removing the parts of the plating wires to be exposed at side surfaces of the wiring board.

### Fourth Embodiment

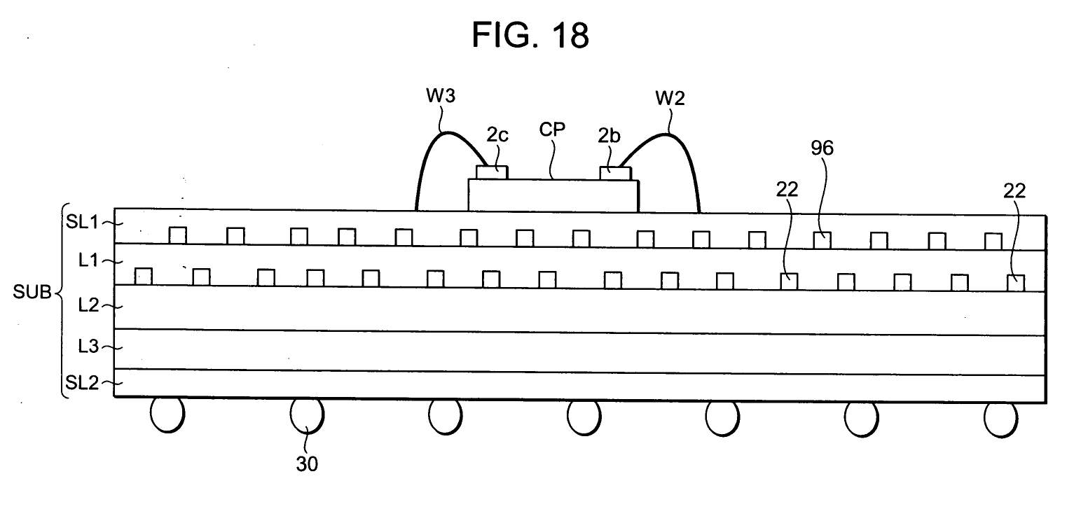

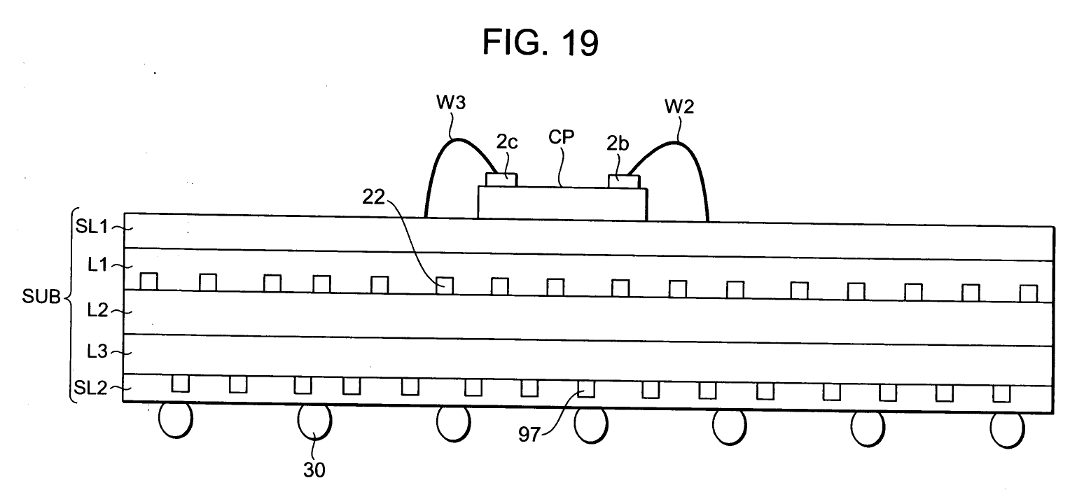

Hereinafter, an explanation will be made of a wiring board in accordance with a fourth embodiment using FIGS. 18 and 19. The fourth embodiment differs from the first embodiment in the pattern of the conductive layer Lc1 and in the pattern of the conductive layer Lc4. Note that both the conductive layers Lc1 and Lc4 are formed by means of electroplating.

FIG. 18 shows a side elevational view corresponding to FIG. 4 in the first embodiment. In the present embodiment, as shown in FIG. 18, a plurality of front faces 96 constituting a conductive layer Lc1 are exposed at the side surfaces of a wiring board SUB. There are also exposed a plurality of the protruding faces 22 of wiring lines constituting a conductive layer Lc2.

When FIG. 18 is viewed from the front side thereof, it is understood that a plurality of front faces 96 and a plurality of protruding faces 22 are disposed in an alternate manner. In other words, the front faces 96 and the protruding faces 22 are disposed in a zigzag pattern. That is, each front face 96 is disposed above a position between mutually adjacent protruding faces 22. This also means that each protruding face 22 is disposed below a position between mutually adjacent front faces 96.

If the insulating layer L1 is too thin, the front faces 96 may be overextended to the protruding faces 22, or vice versa, at side surfaces of the wiring board SUB during dicing, thereby resulting in contact between the front faces 96 and the protruding faces 22. However, if disposed in a zigzag pattern, the front faces 96 and the protruding faces 22 are inhibited from coming into contact with each other as described above.

FIG. 19 shows a side elevational view corresponding to FIG. 6 in the first embodiment. In the present embodiment, as shown in FIG. 19, a plurality of the front faces 97 of wiring lines constituting the conductive layer Lc4 are exposed at the side surfaces of the wiring board SUB. There are also exposed a plurality of the protruding faces 22 of wiring lines constituting the conductive layer Lc2.

In the present embodiment, when FIG. 19 is viewed from the front side thereof, it is understood that a plurality of front faces 97 and a plurality of protruding faces 22 are disposed in an alternate manner. In other words, the front faces 97 and the protruding faces 22 are disposed in a zigzag pattern. That is, each front face 97 is disposed above a position between mutually adjacent protruding faces 22. This also means that each protruding face 22 is disposed below a position between mutually adjacent front faces 97.

If the insulating layers L2 and L3 are too thin, the front faces 97 may be extended to the protruding faces 22, or vice versa, at the side surfaces of the wiring board SUB during dicing, thereby resulting in contact between the front faces 97 and the protruding faces 22. However, if disposed in a zigzag pattern, the front faces 97 and the protruding faces 22 can be inhibited from coming into contact with each other as described above. An example has been given above wherein the protruding faces 22 and the front faces 96 and 97 are disposed so that the protruding faces 22 are configurationally correlated with the front faces 96 and with the front faces 97, respectively, by a zigzag pattern formed at a side surface of the wiring board. Note that the protruding faces 22 and the solder balls 30 or solder ball pads (not shown in the figure) may be disposed so that the protruding faces 22 are configurationally correlated with the solder balls 30 or solder ball pads by a zigzag pattern formed at a side surface of the wiring board.

### Fifth Embodiment

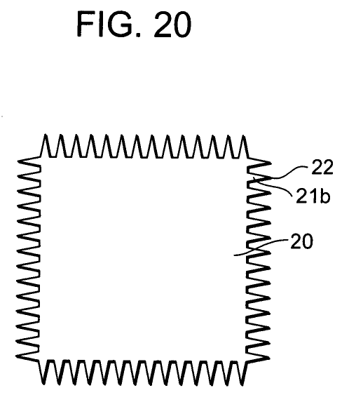

Hereinafter, an explanation will be made of a wiring board in accordance with a fifth embodiment using FIG. 20. The fifth embodiment differs from the first embodiment in the pattern of the conductive layer Lc2 as viewed from the top surface thereof.

The conductive layer Lc2 has a plane part 20 and a plurality of protruding parts 21b. In the present embodiment, the top-view shape of the protruding parts 21b extending from the plane part 20 to protruding faces 22 is triangular. The protruding parts 21b become thinner as they extend from the plane part 20 toward the protruding faces 22. That is, the protruding parts 21b are thinner in a portion thereof closer to the protruding faces 22 and are thicker in a portion thereof closer to the plane part 20. Accordingly, the area of the protruding faces 22 can be made extremely small. Consequently, the functionality of the protruding parts 21b in the present embodiment as conductor rods is enhanced to a higher degree than in the first embodiment. As a result, it is possible to effectively protect the solder balls 30 to be protected from static electricity.

The technical scope of the present invention is not limited to the above-described embodiments. While descriptions have been made taking as an example a wiring board on which a bare chip is mounted, the present invention is not limited to this wiring board. For example, the wiring board may be a ceramic substrate or substrates of other types. In addition, the present invention is also applicable to a large-sized wiring board, such as a so-called mother board. That is, the present invention is also applicable to a printed board on which packaged electronic components are mounted in addition to such electronic components as capacitors. In addition, the shape of a wiring board is optional and, therefore, the top-view shape thereof is not limited to a rectangle. That is, the wiring board may be L-shaped or of other shapes.

Furthermore, the top-view shape of protruding parts is only a matter of pattern formation. Accordingly, the top-view shape can be rectangular, triangular, curved or circular. In addition, the protruding parts may be provided in the conductive layer Lc3, in addition to the conductive layer Lc2. That is, the protruding parts may be provided in the plane part 23, rather than in the plane part 20. Needless to say, the protruding parts may be provided in the plane part 23, in addition to the plane part 20. That is, the functionality of a conductor rod may be added to the power supply plane, in addition to the ground plane. A plurality of ground planes and a plurality of power supply planes may be provided depending the number of layers of the wiring board SUB. While in the present specification, each embodiment is described on the premise that there are provided three insulating layers and four conductive layers. However, the number of insulating layers and the number of conductive layers are not limited to those shown in the above-described embodiments. A desired number of layers may be used for the insulating layers and conductive layers, respectively.

Furthermore, after forming the solder resist layer SL1, the conductive layer Lc1 may be formed thereon. Likewise, after forming the solder resist layer SL2, the conductive layer Lc4 may be formed thereon. It is also possible to partially remove the conductive layer Lc1 by etching back. A resin may be applied to the top surface of the wiring board SUB to seal the semiconductor chip CP.

Note further that a method of forming the patterns of the conductive layers Lc1 and Lc4 is optional. That is, as in the first embodiment, the patterns of the conductive layers Lc1 and Lc4 may be formed by means of electroplating. As in the second embodiment, the patterns of the conductive layers Lc1 and Lc4 may be formed using other methods not requiring electroplating or a method in which plating wires are removed after plating even if electroplating is required. In addition, as in the third embodiment, parts of the patterns of conductive layers Lc1 and Lc4 exposed at side surfaces of the wiring board may be partially removed after forming these conductive layers by means of electroplating.

What is claimed is:

1. A wiring board comprising:
a first insulating layer;
a first conductive layer formed over said first insulating layer; and
a second insulating layer formed over said first conductive layer,
wherein said board has a top surface and a side surface, and
wherein said first conductive layer is parallel to said board and is coupled to receive a first power supply potential, said first conductive layer having a first portion and a second portion, said second portion including plurality of segments extending from said first portion to said side surface, so that edges of said segments are disposed at the side surface of said wiring board.

2. The wiring board according to claim 1, further comprising a first principal surface layer and a second principal surface layer opposed to each other and electrical connection between said first and second principal surface layers.

3. The wiring board according to claim 2, wherein said first portion is formed between said first and second principal surface layers, and wherein at least one of signal lines between said principal surface layers extends through a plane in which said conductive layer is formed and is isolated from said conductive layer.

4. The wiring board according to claim 2, further comprising a semiconductor chip on said first principal surface layer and a plurality of external terminals on said second principal surface layer.

5. The wiring board according to claim 4, wherein said external terminals are formed in a shape projecting above said second principal surface layer.

6. The wiring board according to claim 1, wherein said second portion has a first set of said segments, and wherein said segments in said first set are parallel with each other and disposed adjacently at said side surface.

7. The wiring board according to claim 1, wherein said second portion has a first set of said segments and a second set of different ones of said segments, said segments in said first set being parallel to each other, said segments in said second set being parallel to each other, wherein said side surface includes a first and a second side faces, wherein said first set extends toward said first side face, and wherein said second set extends toward said second side face.

8. The wiring board according to claim 1, wherein said segments extend from said first portion toward the closest side face among side faces of said wiring board.

9. The wiring board according to claim 1, wherein at least one of said segments has its width substantially the same as it extends from said first portion to said side surface.

10. The wiring board according to claim 1, wherein exposed edges of said segments substantially correspond to the side surface of said wiring board.

11. The wiring board according to claim 1, wherein said segments become thinner as said segments extend toward said side surface.

12. The wiring board according to claim 1, further including a wiring layer in which a plurality of wiring lines are formed, at least one of said lines extending toward the side surface of said wiring board.

13. The wiring board according to claim 12, wherein said at least one of said lines does not reach said side surface of said wiring board.

14. The wiring board according to claim 12, wherein a plural ones of said wiring lines extend to said side surface, front faces of said wiring lines being exposed at said side surface, wherein said front faces and said edges of said segments are disposed in a zigzag pattern at the side surface of said wiring board.

15. The wiring board according to claim 12, wherein said front faces of said wiring lines are disposed vertically above or below said edges of said segments at the side surface of said wiring board.

16. The wiring board according to claim 1, further including external terminals disposed on said wiring board, wherein said external terminals are surrounded by said edges of said segments.

17. The wiring board according to claim 16, wherein said external terminals are projecting electrodes.

18. The wiring board according to claim 1, wherein said wiring board is formed by thermocompression-bonding said first insulating layer and said second insulating layer to each other with said first conductive layer held therebetween.

19. The wiring board according to claim 1, further comprising external terminals to be protected, wherein said side surface has a plurality of said faces, respective one or ones of said faces that is the closest to respective ones of said terminals being associated with at least one of said edges.

20. The wiring board according to claim 19, wherein said external terminals to be protected are projecting electrodes.
